(19) United States
(12) Patent Application Publication
(10) Pub. No.: US 2026/0143806 A1
(43) Pub. Date: May 21, 2026

(54) STACKED DEVICE CONTACT CONFIGURATIONS FOR STAGGERED SOURCE/DRAIN REGIONS

(71) Applicant: International Business Machines Corporation, Armonk, NY (US)

(72) Inventors: Debarghya Sarkar, Latham, NY (US); Ruilong Xie, Niskayuna, NY (US); Abir Shadman, Albany, NY (US); Junli Wang, Slingerlands, NY (US)

(21) Appl. No.: 18/952,101

(22) Filed: Nov. 19, 2024

(51) Int. Cl. H01L 27/092; H01L 21/822; H01L 21/8238; H01L 29/06; H01L 29/417; H01L 29/423; H01L 29/66; H01L 29/775; H01L 29/786

(52) U.S. Cl. CPC H10D 84/856; H10D 30/014; H10D 30/43; H10D 30/6729; H10D 30/6735; H10D 30/6757; H10D 62/121; H10D 84/017; H10D 84/0186; H10D 84/038; H10D 88/01

(57) ABSTRACT

A semiconductor device includes first and second source/drain regions, where the first source/drain region is at least partially laterally offset from the second source/drain region. The semiconductor device includes a first interlayer via extending into at least a portion of the first source/drain region, where the first interlayer via is isolated from the first source/drain region by a first dielectric liner, and a second interlayer via connected to the second source/drain region and to the first interlayer via, where the second interlayer via extends into at least a portion of the second source/drain region. The semiconductor device also includes a frontside contact connected to the first source/drain region, where the frontside contact is adjacent to, and isolated from, the second interlayer via.

### BACKGROUND

The present application relates to semiconductors, and more specifically, to techniques for forming semiconductor structures. Semiconductors and integrated circuit chips have become ubiquitous within many products, particularly as they continue to decrease in cost and size. There is a continued desire to reduce the size of structural features and/or to provide a greater amount of structural features for a given chip size. Miniaturization, in general, allows for increased performance at lower power levels and lower costs. Present technology is at or approaching atomic level scaling of certain micro-devices such as logic gates, field-effect transistors (FETs), and capacitors.

### SUMMARY

Embodiments described herein provide techniques for forming contact configurations for stacked devices having staggered active regions.

In one embodiment, a semiconductor device includes first and second source/drain regions, where the first source/drain region is at least partially laterally offset from the second source/drain region. The semiconductor device includes a first interlayer via extending into at least a portion of the first source/drain region, where the first interlayer via is isolated from the first source/drain region by a first dielectric liner, and a second interlayer via connected to the second source/drain region and to the first interlayer via. The second interlayer via extends into at least a portion of the second source/drain region. The semiconductor device also includes a frontside contact connected to the first source/drain region, where the frontside contact is adjacent to, and isolated from, the second interlayer via.

In another embodiment, a semiconductor device includes a first transistor device comprising a first gate structure, a first source/drain region, a frontside source/drain contact connected to the first source/drain region, and a first set of channel layers connected to the first source/drain region. The semiconductor device includes a second transistor device vertically stacked with the first transistor device, comprising a second gate structure, a second source/drain region, and a second set of channel layers connected to the second source/drain region, where the first source/drain region does not vertically overlap with the second source/drain region. The semiconductor device also includes a first interlayer via extending into at least a portion of the first source/drain region, where the first interlayer via is isolated from the first source/drain region by a first dielectric liner, and a second interlayer via connected to the second source/drain region and to the first interlayer via. The frontside source/drain contact is adjacent to the second interlayer via and isolated from the second interlayer via by a second dielectric liner.

In yet another embodiment, a method includes forming a first source/drain region, forming a second source/drain region that is at least partially laterally offset from the first source/drain region. The method also includes forming a first interlayer via extending into at least a portion of the first source/drain region, where the first interlayer via is isolated from the first source/drain region by a first dielectric liner. Additionally, the method includes forming a second interlayer via connected to the second source/drain region and to the first interlayer via, where the second interlayer via extends into at least a portion of the second source/drain region, and forming a frontside contact connected to the first source/drain region, where the frontside contact is adjacent to, and isolated from, the second interlayer via.

These and other features and advantages of embodiments described herein will become more apparent from the accompanying drawings and the following detailed description.

### BRIEF DESCRIPTION OF THE DRAWINGS

FIG. 1 depicts a top view of a semiconductor structure indicating X1, X2, and Y cross-section locations on which the cross-sectional views of FIGS. 2A-16C are based.

FIG. 2A depicts a first cross-sectional view corresponding to the line X1 in FIG. 1 illustrating the semiconductor structure of FIG. 1 during an intermediate step of a method of fabricating a nanosheet transistor structure, according to an illustrative embodiment.

FIG. 2B depicts a second cross-sectional view corresponding to the line X2 in FIG. 1 illustrating the semiconductor structure of FIG. 1 during the intermediate step of a method of fabricating a nanosheet transistor structure, according to an illustrative embodiment.

FIG. 2C depicts a third cross-sectional view corresponding to the line Y in FIG. 1 illustrating the semiconductor structure of FIG. 1 during the intermediate step of a method of fabricating a nanosheet transistor structure, according to an illustrative embodiment.

FIG. 3A depicts a first cross-sectional view corresponding to the line X1 in FIG. 1 following a first interlayer via etching process, according to an illustrative embodiment.

FIG. 3B depicts a second cross-sectional view corresponding to the line X2 in FIG. 1 following the first interlayer via etching process, according to an illustrative embodiment.

FIG. 3C depicts a third cross-sectional view corresponding to the line Y in FIG. 1 following the first interlayer via etching process, according to an illustrative embodiment.

FIG. 4A depicts a first cross-sectional view corresponding to the line X1 in FIG. 1 following deposition and recessing of a first liner layer, according to an illustrative embodiment.

FIG. 4B depicts a second cross-sectional view corresponding to the line X2 in FIG. 1 following the deposition and recessing of the first liner layer, according to an illustrative embodiment.

FIG. 4C depicts a third cross-sectional view corresponding to the line Y in FIG. 1 following the deposition and recessing of the first liner layer, according to an illustrative embodiment.

FIG. 5A depicts a first cross-sectional view corresponding to the line X1 in FIG. 1 following metallization of the first interlayer via, according to an illustrative embodiment.

FIG. 5B depicts a second cross-sectional view corresponding to the line X2 in FIG. 1 following the metallization of the first interlayer via, according to an illustrative embodiment.

FIG. 5C depicts a third cross-sectional view corresponding to the line Y in FIG. 1 following the metallization of the first interlayer via, according to an illustrative embodiment.

FIG. 6A depicts a first cross-sectional view corresponding to the line X1 in FIG. 1 following a device bonding process, according to an illustrative embodiment.

FIG. 6B depicts a second cross-sectional view corresponding to the line X2 in FIG. 1 following the device bonding process, according to an illustrative embodiment.

FIG. 6C depicts a third cross-sectional view corresponding to the line Y in FIG. 1 following the device bonding process, according to an illustrative embodiment.

FIG. 7A depicts a first cross-sectional view corresponding to the line X1 in FIG. 1 following a second interlayer via etching process, according to an illustrative embodiment.

FIG. 7B depicts a second cross-sectional view corresponding to the line X2 in FIG. 1 following the second interlayer via etching process, according to an illustrative embodiment.

FIG. 7C depicts a third cross-sectional view corresponding to the line Y in FIG. 1 following the second interlayer via etching process, according to an illustrative embodiment.

FIG. 8A depicts a first cross-sectional view corresponding to the line X1 in FIG. 1 following metallization of the second interlayer via, according to an illustrative embodiment.

FIG. 8B depicts a second cross-sectional view corresponding to the line X2 in FIG. 1 following the metallization of the second interlayer via, according to an illustrative embodiment.

FIG. 8C depicts a third cross-sectional view corresponding to the line Y in FIG. 1 following the metallization of the second interlayer via, according to an illustrative embodiment.

FIG. 9A depicts a first cross-sectional view corresponding to the line X1 in FIG. 1 following a silicidation process, according to an illustrative embodiment.

FIG. 9B depicts a second cross-sectional view corresponding to the line X2 in FIG. 1 following the silicidation process, according to an illustrative embodiment.

FIG. 9C depicts a third cross-sectional view corresponding to the line Y in FIG. 1 following the silicidation process, according to an illustrative embodiment.

FIG. 10A depicts a first cross-sectional view corresponding to the line X1 in FIG. 1 following a first frontside contact etching process, according to an illustrative embodiment.

FIG. 10B depicts a second cross-sectional view corresponding to the line X2 in FIG. 1 following the first frontside contact etching process, according to an illustrative embodiment.

FIG. 10C depicts a third cross-sectional view corresponding to the line Y in FIG. 1 following the first frontside contact etching process, according to an illustrative embodiment.

FIG. 11A depicts a first cross-sectional view corresponding to the line X1 in FIG. 1 following deposition and recessing of a second liner layer, according to an illustrative embodiment.

FIG. 11B depicts a second cross-sectional view corresponding to the line X2 in FIG. 1 following the deposition and recessing of the second liner layer, according to an illustrative embodiment.

FIG. 11C depicts a third cross-sectional view corresponding to the line Y in FIG. 1 following the deposition and recessing of the second liner layer, according to an illustrative embodiment.

FIG. 12A depicts a first cross-sectional view corresponding to the line X1 in FIG. 1 following a second frontside contact etching process, according to an illustrative embodiment.

FIG. 12B depicts a second cross-sectional view corresponding to the line X2 in FIG. 1 following the second frontside contact etching process, according to an illustrative embodiment.

FIG. 12C depicts a third cross-sectional view corresponding to the line Y in FIG. 1 following the second frontside contact etching process, according to an illustrative embodiment.

FIG. 13A depicts a first cross-sectional view corresponding to the line X1 in FIG. 1 following an ashing process and formation of frontside contacts, according to an illustrative embodiment.

FIG. 13B depicts a second cross-sectional view corresponding to the line X2 in FIG. 1 following the ashing process and the formation of frontside contacts, according to an illustrative embodiment.

FIG. 13C depicts a third cross-sectional view corresponding to the line Y in FIG. 1 following the ashing process and the formation of frontside contacts, according to an illustrative embodiment.

FIG. 14A depicts a first cross-sectional view corresponding to the line X1 in FIG. 1 following frontside interconnect formation and carrier wafer bonding, according to an illustrative embodiment.

FIG. 14B depicts a second cross-sectional view corresponding to the line X2 in FIG. 1 following the frontside interconnect formation and the carrier wafer bonding, according to an illustrative embodiment.

FIG. 14C depicts a third cross-sectional view corresponding to the line Y in FIG. 1 following the frontside interconnect formation and the carrier wafer bonding, according to an illustrative embodiment.

FIG. 15A depicts a first cross-sectional view corresponding to the line X1 in FIG. 1 following wafer flipping, semiconductor substrate and etch stop layer removal, and backside interlayer dielectric (ILD) layer formation, according to an illustrative embodiment.

FIG. 15B depicts a second cross-sectional view corresponding to the line X2 in FIG. 1 following the wafer flipping, the semiconductor substrate and etch stop layer removal, and the backside ILD layer formation, according to an illustrative embodiment.

FIG. 15C depicts a third cross-sectional view corresponding to the line Y in FIG. 1 following the wafer flipping, the semiconductor substrate and etch stop layer removal, and the backside ILD layer formation, according to an illustrative embodiment.

FIG. 16A depicts a first cross-sectional view corresponding to the line X1 in FIG. 1 following formation of a backside power delivery network (BSPDN), according to an illustrative embodiment.

FIG. 16B depicts a second cross-sectional view corresponding to the line X2 in FIG. 1 following the formation of the BSPDN, according to an illustrative embodiment.

FIG. 16C depicts a third cross-sectional view corresponding to the line Y in FIG. 1 following the formation of the BSPDN, according to an illustrative embodiment.

### DETAILED DESCRIPTION

Illustrative embodiments may be described herein in the context of illustrative methods for forming contact configurations for stacked devices with staggered source/drain regions, along with illustrative apparatus, systems, and devices formed using such methods. However, it is to be understood that embodiments described herein are not limited to the illustrative methods, apparatus, systems, and devices but instead are more broadly applicable to other suitable methods, apparatus, systems, and devices.

It is to be understood that the various features shown in the accompanying drawings are schematic illustrations that are not necessarily drawn to scale. Moreover, the same or similar reference numbers are used throughout the drawings to denote the same or similar features, elements, or structures, and thus, a detailed explanation of the same or similar features, elements, or structures will not be repeated for each of the drawings. Further, the terms “exemplary” and “illustrative” as used herein mean “serving as an example, instance, or illustration.” Any embodiment or design described herein as “exemplary” or “illustrative” is not to be construed as preferred or advantageous over other embodiments or designs.

A FET is a transistor having a source, a gate, and a drain, and having action that depends on the flow of carriers (electrons or holes) along a channel that runs between the source and drain. Current through the channel between the source and drain may be controlled by a transverse electric field under the gate.

FETs are widely used for switching, amplification, filtering, and other tasks. FETs include metal-oxide-semiconductor (MOS) FETs (MOSFETs). Complementary MOS (CMOS) devices are widely used, where both n-type and p-type transistors (nFET and pFET) are used to fabricate logic and other circuitry. Source and drain regions of a FET are typically formed by adding dopants to target regions of a semiconductor body on either side of a channel, with the gate being formed above the channel. The gate includes a gate dielectric over the channel and a gate conductor over the gate dielectric. The gate dielectric is an insulator material that prevents large leakage current from flowing into the channel when voltage is applied to the gate conductor while allowing applied gate voltage to produce a transverse electric field in the channel.

Various techniques may be used to reduce the size of FETs. One technique is through the use of fin-shaped channels in fin field-effect transistors (FinFET). Before the advent of FinFET arrangements, CMOS devices were typically substantially planar along the surface of the semiconductor substrate, with the exception of the FET gate disposed over the top of the channel. FinFETs utilize a vertical channel structure, increasing the surface area of the channel exposed to the gate. Thus, in FinFET structures, the gate can more effectively control the channel, as the gate extends over more than one side or surface of the channel. In some FinFET arrangements, the gate encloses three surfaces of the three-dimensional channel, rather than being disposed over just the top surface of a traditional planar channel.

Another technique useful for reducing the size of FETs is through the use of stacked nanosheet channels formed over a semiconductor substrate. Stacked nanosheets may be two-dimensional nanostructures, such as sheets having a thickness range on the order of 1 to 20 nanometers (nm). Nanosheets and nanowires are viable options for scaling to 7 nm and beyond. A general process flow for forming a nanosheet stack involves selectively removing sacrificial layers, which may be formed of silicon germanium (SiGe), between sheets of channel material, which may be formed of silicon (Si).

For continued scaling (e.g., to 2.5 nm and beyond), next-generation stacked FET devices may be used. Next-generation stacked FET devices provide a complex gate-all-around (GAA) structure. Conventional GAA FETs, such as nanosheet FETs, stack multiple p-type nanowires or nanosheets on top of each other in one device, and may stack multiple n-type nanowires or nanosheets on top of each other in another device. Next-generation stacked FET structures provide improved track height scaling, leading to structural gains (e.g., 30-40% for different types of devices such as logic devices, static random-access memory (SRAM) devices). In next-generation stacked FET structures, n-type and p-type nanowires or nanosheets are stacked on each other, eliminating n-to-p separation bottlenecks and reducing the device area footprint.

As discussed above, various techniques may be used to reduce the size of FETs, including through the use of fin-shaped channels in FinFET devices, through the use of stacked nanosheet channels formed over a semiconductor substrate, and next-generation complementary FET (CFET) devices. Although embodiments described herein are discussed in connection with nanosheet stacks, the embodiments are not necessarily limited thereto, and may similarly apply to nanowire stacks.

Conventional techniques for designing and fabricating stacked semiconductor devices (e.g., stacked FETs) with staggered active regions can be challenging. For example, such techniques often require a compromise between achieving a small cell height and providing a reliable architecture where contacts do not cause unintended shorts between different structures within the device. Designs that require a top source/drain region and bottom source/drain region within a single canyon or trench to be connected at a backside and a frontside of a semiconductor device, respectively, are particularly challenging. Existing techniques fail to provide a reliable source/drain contact configuration for stacked devices without compromising on cell height and/or overall performance.

Some embodiments described herein can achieve reliable source/drain contact schemes for staggered stacked semiconductor devices without sacrificing cell height and/or performance. For example, at least some embodiments include using one or more dielectric barrier layers and interlayer via structures so that source/drain regions can be connected to the opposite interconnect layer (e.g., top source/drain region connected to a backside interconnect layer and/or bottom source/drain region connected to a frontside interconnect layer) without increasing cell height or reducing performance.

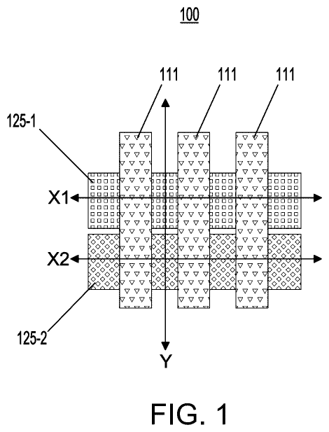

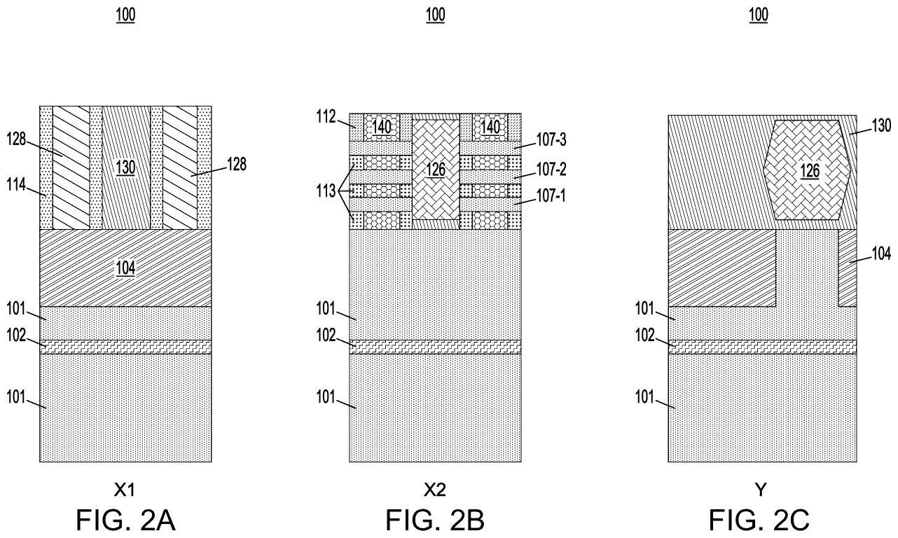

FIG. 1 illustrates a top view of a semiconductor structure 100 with lines X1, X2, and Y on which the cross-sectional views of FIGS. 2A-16C are based, according to an illustrative embodiment. The semiconductor structure 100 includes gate regions 111 and active regions 125-1 and 125-2 (collectively “active regions 125”). The gate regions 111 correspond to areas of the semiconductor structure 100 where gate structures 140 and 180 are formed, and the active regions 125 correspond to areas of the semiconductor structure 100 where source/drain regions 126 and 127 are formed, as shown in FIGS. 2A-16C. In some embodiments, the active regions 125 are vertically stacked and staggered (e.g., laterally offset) along a direction of the gate regions 111. In the example shown in FIG. 1, the active regions 125-1 and 125-2 do not overlap along the direction of the gate regions 111. However, it should be noted that in other embodiments the active regions 125-1 and 125-2 can be partially laterally offset so that they partially overlap along the direction of the gate regions 111.

Referring to FIG. 1 and to the cross-sectional views in FIGS. 2A, 2B, and 2C, which respectively correspond to the lines X1, X2, and Y in FIG. 1, the semiconductor structure 100 includes a stacked structure of first channel layers 107-1, 107-2, and 107-3 (collectively “channel layers 107”) and the gate structures 140. In an illustrative embodiment, the channel layers 107 comprise silicon. In an illustrative embodiment, the gate structures 140 are formed after a replacement metal gate (RMG) process in which sacrificial layers are removed and replaced with the gate structures 140. The lowermost gate structures 140 are formed on a top portion of a semiconductor substrate 101.

While the channel layers 107 include three channel layers in FIGS. 2A-2C, embodiments described herein are not necessarily limited to the shown number of channel layers 107, and there may be more or less layers in the same alternating configuration depending on design constraints.

In illustrative embodiments, each gate structure 140 includes a gate dielectric layer such as, for example, a high-K dielectric layer including, but not necessarily limited to, HfO₂ (hafnium oxide), ZrO₂ (zirconium dioxide), hafnium zirconium oxide, Al₂O₃ (aluminum oxide), and Ta₂O₅ (tantalum oxide). Examples of high-k materials also include, but are not necessarily limited to, metal oxides such as hafnium silicon oxynitride, lanthanum oxide, lanthanum aluminum oxide, zirconium oxide, zirconium silicon oxide, zirconium silicon oxynitride, tantalum oxide, titanium oxide, barium strontium titanium oxide, barium titanium oxide, strontium titanium oxide, yttrium oxide, aluminum oxide, lead scandium tantalum oxide, and lead zinc niobate. According to an embodiment, the gate structures 140 each include a metal gate portion including a work-function metal (WFM) layer, including but not necessarily limited to, for a pFET, titanium nitride (TiN), tantalum nitride (TaN), or ruthenium (Ru), and for an nFET, TiN, titanium aluminum nitride (TiAlN), titanium aluminum carbon nitride (TiAlCN), titanium aluminum carbide (TiAlC), tantalum aluminum carbide (TaAlC), tantalum aluminum carbon nitride (TaAlCN) or lanthanum (La) doped TiN, TaN, which can be deposited on the gate dielectric layer. The metal gate portions can also each further include a gate metal layer including, but not necessarily limited to metals, such as tungsten (W), cobalt (Co), zirconium (Zr), tantalum (Ta), titanium (Ti), aluminum (Al), ruthenium (Ru), copper (Cu), metal carbides, metal nitrides, transition metal aluminides, tantalum carbide, titanium carbide, tantalum magnesium carbide, or combinations thereof deposited on the WFM layer and the gate dielectric layer. It should be appreciated that various other materials may be used for the metal gate portions as desired.

Gate spacers 112 are formed on sides of the gate structures 140. The material of the gate spacers 112 can comprise one or more dielectrics, including, but not necessarily limited to, silicon nitride (SiN), silicon oxynitride (SiON), silicon-carbon-nitride (SiCN), boron nitride (BN), silicon boron nitride (SiBN), silicoboron carbonitride (SiBCN), silicon oxycarbonitride (SiOCN), silicon oxide (SiOₓ) (where x is, for example, 2, 1.99 or 2.01), and combinations thereof. The gate spacers 112 can be formed by any suitable techniques such as deposition followed by directional etching. Deposition may include but is not limited to chemical vapor deposition (CVD), plasma-enhanced CVD (PECVD), radio-frequency CVD (RFCVD), physical vapor deposition (PVD), atomic layer deposition (ALD), molecular beam deposition (MBD), pulsed laser deposition (PLD), and/or liquid source misted chemical deposition (LSMCD). Directional etching may include, but is not limited to, reactive ion etching (RIE).

Inner spacers 113 are disposed on opposite sides of the gate structures 140 under and/or over end portions of the channel layers 107. The material of the inner spacers 113 can comprise a nitride, such as SiN, SiON, SiCN, BN, SiBN, SiBCN, or SiOCN. In an illustrative embodiment, the gate spacers 112 are formed from the same or similar material to that of the inner spacers 113. Like the gate spacers 112, the inner spacers 113 can be formed by any suitable techniques such as deposition followed by directional etching.

The semiconductor substrate 101 comprises semiconductor material including, but not limited to, silicon (Si), III-V and II-V compound semiconductor materials, or other like semiconductor materials. In addition, multiple layers of the semiconductor materials can be used as the semiconductor material of the semiconductor substrate 101.

An etch stop layer 102 is formed in the semiconductor substrate 101. The etch stop layer 102 may comprise a buried oxide (BOX) layer or SiGe, or another suitable material such as a III-V semiconductor epitaxial layer.

Isolation regions 104 (e.g., shallow trench isolation (STI) regions) are formed in the semiconductor substrate 101 between nanosheet stacks comprising the channel layers 107 and the gate structures 140 and adjacent to the source/drain region 126. In illustrative embodiments, the isolation regions 104 comprise a dielectric material fill portion in recessed portions of the semiconductor substrate 101 and a corresponding liner portion formed between the fill portion and the semiconductor substrate 101. The liner portion can be formed of SiN or another suitable material such as SiBCN, SiCOH, SiNCH, etc. The dielectric material fill portion may comprise, for example, silicon nitride (SiN), silicon oxynitride (SiON), silicon-carbon-nitride (SiCN), boron nitride (BN), silicon boron nitride (SiBN), silicoboron carbonitride (SiBCN), silicon oxycarbonitride (SiOCN), and combinations thereof.

The source/drain region 126 is epitaxially grown between the nanosheet stacks. The source/drain region 126 comprises epitaxial layers grown from sides of channel layers 107, for example. The terms “epitaxial growth and/or deposition” and “epitaxially formed and/or grown,” mean the growth of a semiconductor material (crystalline material) on a deposition surface of another semiconductor material (crystalline material), in which the semiconductor material being grown (crystalline over layer) has substantially the same crystalline characteristics as the semiconductor material of the deposition surface (seed material). In an epitaxial deposition process, the chemical reactants provided by the source gases are controlled, and system parameters are set so that depositing atoms arrive at the deposition surface of the semiconductor substrate with sufficient energy to move about on the surface such that the depositing atoms orient themselves to the crystal arrangement of the atoms of the deposition surface. Therefore, an epitaxially grown semiconductor material has substantially the same crystalline characteristics as the deposition surface on which the epitaxially grown material is formed.

The epitaxial deposition process may employ the deposition chamber of a chemical vapor deposition type apparatus, such as metal-organic CVD (MOCVD), rapid thermal CVD (RTCVD), ultra-high vacuum CVD (UHVCVD), or a low-pressure CVD (LPCVD) apparatus. A number of different sources may be used for the epitaxial deposition of the in situ doped semiconductor material. In some embodiments, the gas source for the deposition of an epitaxially formed semiconductor material may include silicon (Si) deposited from silane, disilane, trisilane, tetrasilane, hexachlorodisilane, tetrachlorosilane, dichlorosilane, trichlorosilane, and combinations thereof. In other examples, when the semiconductor material includes germanium, a germanium gas source may be selected from the group consisting of germane, digermane, halogermane, dichlorogermane, trichlorogermane, tetrachlorogermane and combinations thereof.

An interlayer dielectric (ILD) layer 130 fills in portions on and around the source/drain region 126. The ILD layer 130 is deposited using deposition techniques such as CVD, PECVD, RFCVD, PVD, ALD, MBD, PLD, and/or LSMCD, followed by a planarization process, such as CMP. The ILD layer 130 may comprise, for example, SiOₓ, SiOC, SiOCN or some other dielectric material.

As used herein, “frontside” or “first side” refers to a side on top of the semiconductor substrate 101 and/or in front of, on top of, or in an upward direction from the stacked gate and channel layers of the transistors in the orientation shown in the cross-sectional figures. As used herein, “backside” or “second side” refers to a side below the semiconductor substrate 101 and/or behind, below, or in a downward direction from the stacked gate and channel layers of the transistors in the orientation shown in the cross-sectional figures (for example, opposite the “frontside”).

Vertical sidewalls 114 and a dielectric fill layer 128 are formed in regions resulting from one or more gate cuts in the ILD layer 130, as shown in FIG. 2A. The vertical sidewalls 114 are formed on the sides of the openings resulting from the gate cuts. The material of the vertical sidewalls 114 can comprise a nitride, such as SiN, SiON, SiCN, BN, SiBN, SiBCN or SiOCN. In an illustrative embodiment, the vertical sidewalls 114 are formed from the same or similar material to that of the gate spacers 112 and/or the inner spacers 113. The material of the dielectric fill layer 128 is deposited using deposition techniques, such as CVD, PECVD, RFCVD, PVD, ALD, MBD, PLD, and/or LSMCD, followed by a planarization process, such as CMP. The dielectric material of the dielectric fill layer 128 may comprise an oxide or another suitable dielectric material.

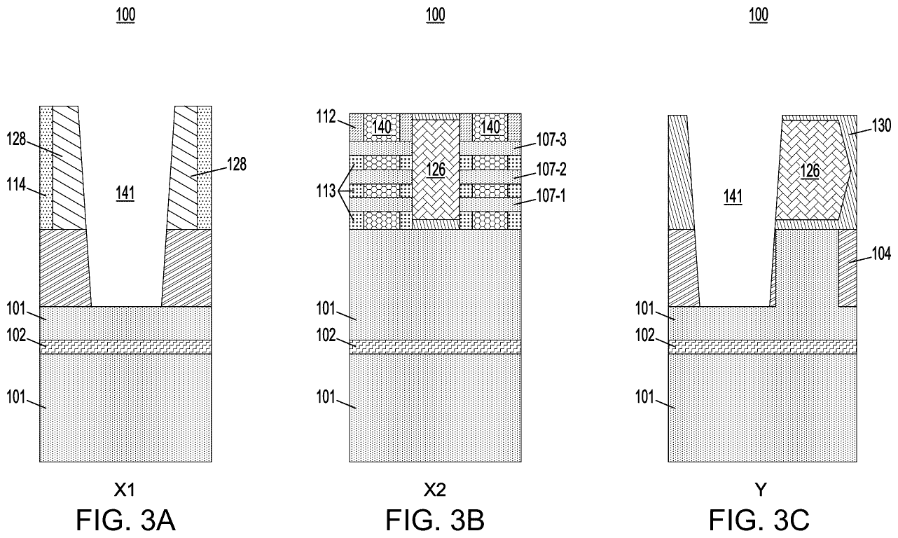

FIGS. 3A-3C show cross-sectional views, which respectively correspond to the lines X1, X2, and Y in FIG. 1 of the semiconductor structure 100 following a first interlayer via etching process, according to an illustrative embodiment. The first interlayer via etching process removes portions of the isolation regions 104, the vertical sidewalls 114, the dielectric fill layer 128, the ILD layer 130, and the source/drain region 126 to form openings 141. For example, the openings 141 can be formed using one or more dry etching processes (e.g., using a RIE and/or ion beam etch (IBE) process), a wet chemical etching process, or a combination of these etching processes.

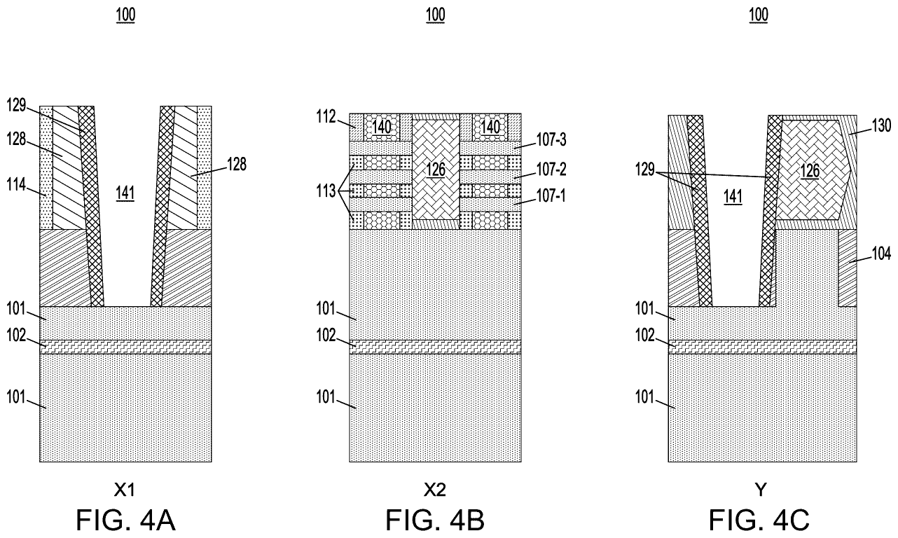

FIGS. 4A-4C show cross-sectional views, which respectively correspond to the lines X1, X2, and Y in FIG. 1 of the semiconductor structure 100 following deposition and recessing of a dielectric liner layer 129, according to an illustrative embodiment. The dielectric liner layer 129 is formed on the sides and bottom of the openings 141. In some embodiments, the dielectric liner layer 129 is formed using a conformal dielectric liner deposition process followed by an etching process, such as RIE. The etching process can remove the bottom portion of the dielectric liner layer 129 to expose the semiconductor substrate 101. The dielectric liner layer 129 may be formed of a suitable dielectric material, such as SiN, SiBCN, SiCOH, SiNCH, etc.

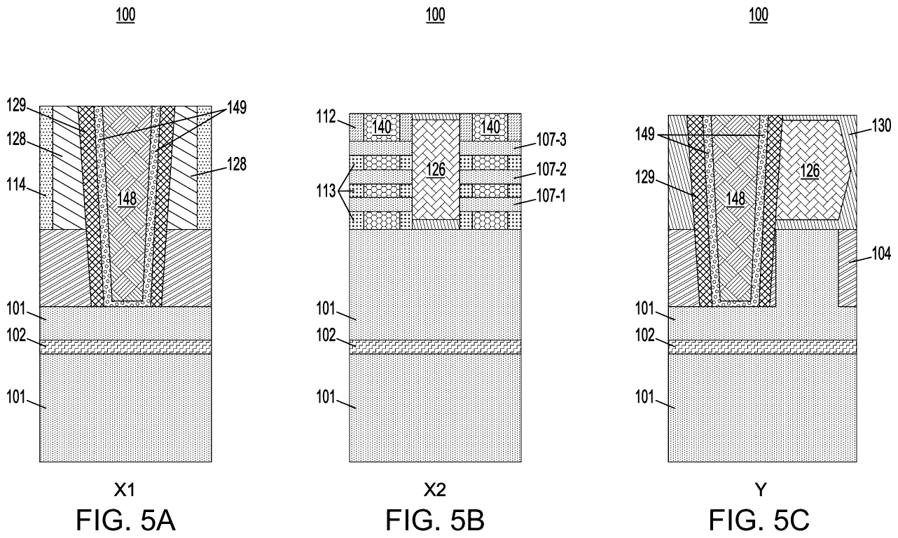

FIGS. 5A-5C show cross-sectional views, which respectively correspond to the lines X1, X2, and Y in FIG. 1 of the semiconductor structure 100 following a first interlayer via metallization process, according to an illustrative embodiment. The first interlayer via metallization process includes depositing a metal liner layer 149 and a conductive layer 148 in the openings 141, which collectively form a bottom interlayer via. The metal liner layer 149 is deposited on side surfaces of the dielectric liner layer 129 and on exposed portions of the semiconductor substrate 101. According to one or more embodiments, deposition of the metal liner layer 149 can be performed using a conformal deposition technique such as ALD or CVD. Deposition of the conductive layer 148 can be performed using one or more deposition techniques including CVD, PECVD, PVD, ALD, MBD, PLD, LSMCD, and/or spin-on coating. Deposition of the conductive layer 148 and the metal liner layer 149 may be followed by planarization using a planarization process, such as CMP, to remove excess material from the top surface of the semiconductor structure 100.

In some embodiments, the metal liner layer 149 includes metals such as Ti, Co, scandium (Sc), and/or chromium (Cr). The conductive layer 148 includes electrically conductive material including, but not necessarily limited to, W, Co, Zr, Ta, Ti, Al, Ru, and/or Cu.

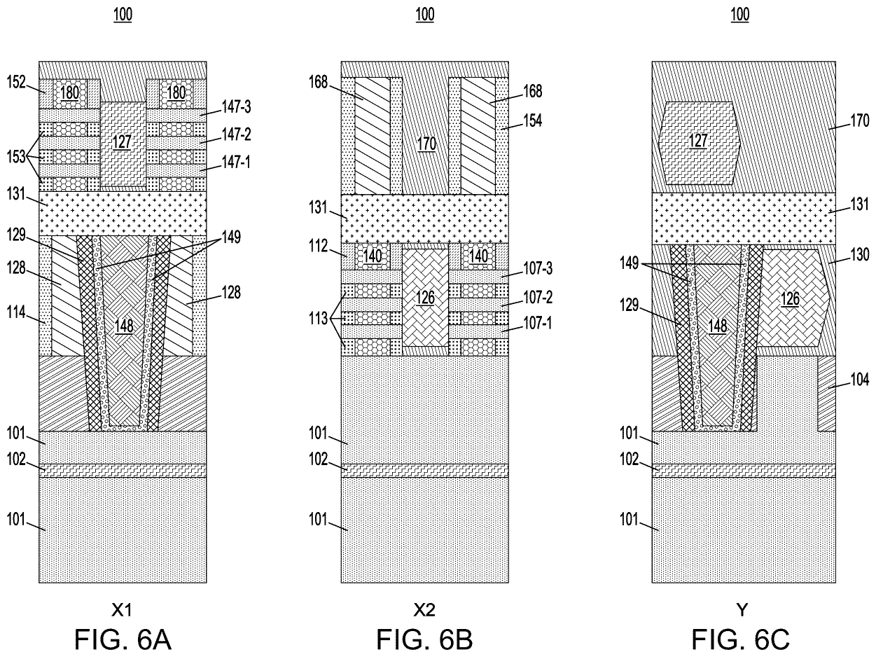

FIGS. 6A-6C show cross-sectional views, which respectively correspond to the lines X1, X2, and Y in FIG. 1 of the semiconductor structure 100 following a device bonding process, according to an illustrative embodiment. The device bonding process can include forming half of a bonding oxide layer 131 on top of the gate spacers 112, the vertical sidewalls 114, the dielectric fill layer 128, the dielectric liner layer 129, the ILD layer 130, the gate structures 140, the metal liner layer 149, and the conductive layer 148. The other half of the bonding oxide layer 131 is formed over a stacked structure comprising alternating layers of sacrificial material (e.g., silicon germanium (SiGe)) and channel material (e.g., silicon) over a silicon substrate (not shown). The two halves of the bonding oxide layer 131 are bonded, for example, using an oxide-oxide bonding process.

The silicon substrate over the stacked structure is removed, and the stacked structure is processed to form the semiconductor structure 100 as shown in FIGS. 6A-6C. More specifically, the semiconductor structure 100 includes the source/drain region 127, a stacked structure of channel layers 147-1, 147-2, and 147-3 (collectively “channel layers 147”) and gate structures 180. While the channel layers 147 include three channel layers in FIGS. 6A-6C, embodiments described herein are not necessarily limited to the shown number of channel layers 147, and there may be more or less layers in the same alternating configuration depending on design constraints. The semiconductor structure 100 also includes gate spacers 152, inner spacers 153, vertical sidewalls 154, a dielectric fill layer 168, and an ILD layer 170. In some embodiments, the elements above the bonding oxide layer 131 shown in FIGS. 6A-6C can be formed using similar techniques and materials as described for the elements below the bonding oxide layer 131 in conjunction with FIGS. 1-2C.

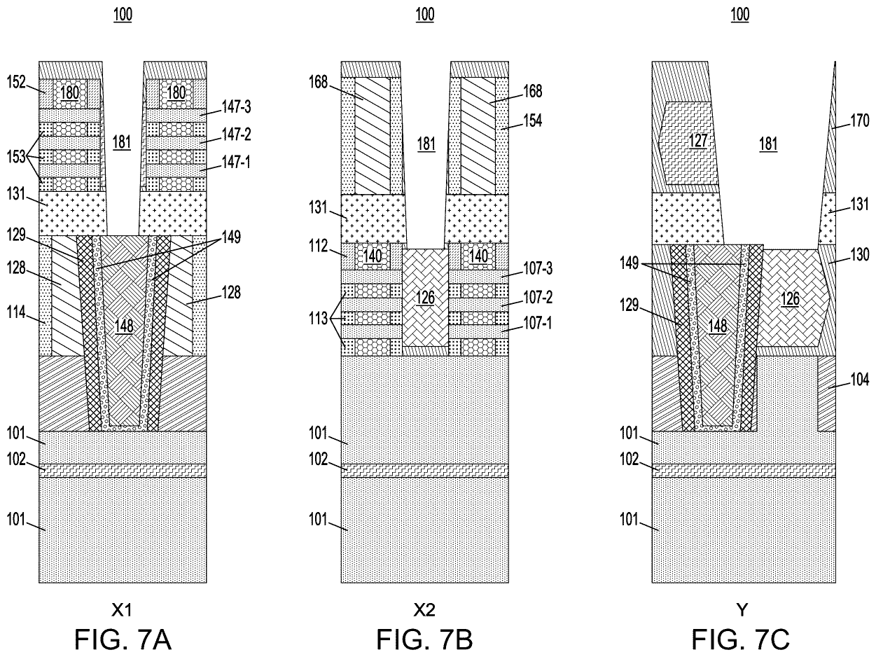

FIGS. 7A-7C show cross-sectional views, which respectively correspond to the lines X1, X2, and Y in FIG. 1 of the semiconductor structure 100 following a second interlayer via etching process, according to an illustrative embodiment. The second interlayer via etching process removes portions of the source/drain region 127, the bonding oxide layer 131, the ILD layers 130 and 170 to form openings 181 that expose portions of the source/drain region 126, the dielectric liner layer 129, the metal liner layer 149, and the conductive layer 148, as shown. For example, the openings 181 can be formed using one or more dry etching processes (e.g., RIE and/or IBE process), a wet chemical etching process, or a combination of these etching processes.

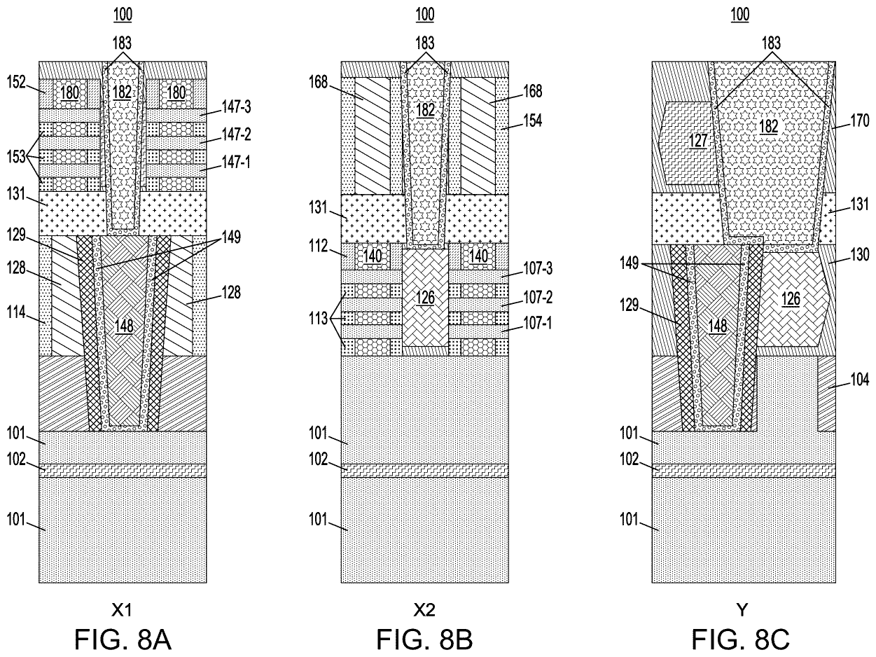

FIGS. 8A-8C show cross-sectional views, which respectively correspond to the lines X1, X2, and Y in FIG. 1 of the semiconductor structure 100 following a second interlayer via metallization process, according to an illustrative embodiment. The second interlayer via metallization process includes depositing a metal liner layer 183 and a conductive layer 182 in the openings 181, which collectively form a top interlayer via. In some embodiments, the metal liner layer 183 and the conductive layer 182 can be formed using similar techniques and materials as described for the conductive layer 148 and the metal liner layer 149, respectively.

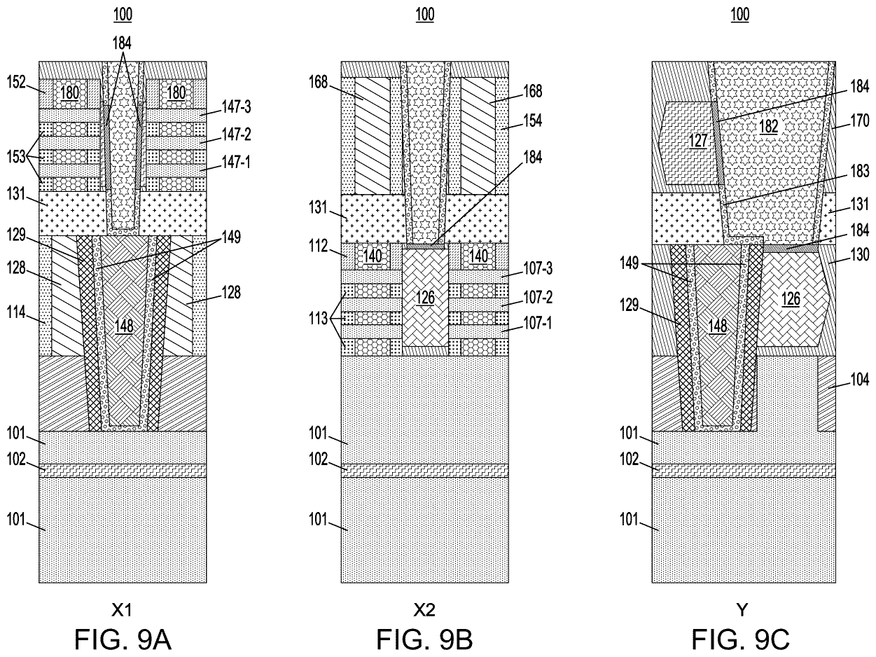

FIGS. 9A-9C show cross-sectional views, which respectively correspond to the lines X1, X2, and Y in FIG. 1 of the semiconductor structure 100 following a silicidation process, according to an illustrative embodiment. The contact silicidation process can include one or more annealing techniques to transform parts of the metal liner layer 183 into a metal silicide with the corresponding source/drain regions 126 and 127, thereby resulting in silicide portions 184. As a non-limiting example, if the metal liner layer 183 is formed of titanium, then the silicide portions 184 can comprise titanium silicide. The annealing techniques can include, but are not limited to, laser anneal, rapid thermal processing (RTP), rapid thermal anneal, or any suitable combination of those techniques.

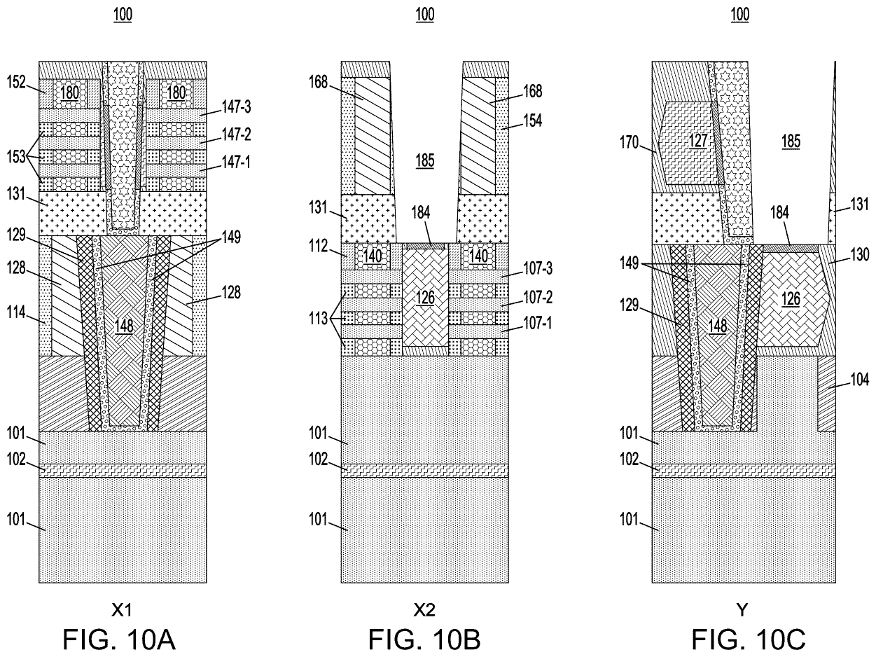

FIGS. 10A-10C show cross-sectional views, which respectively correspond to the lines X1, X2, and Y in FIG. 1 of the semiconductor structure 100 following a first frontside contact etching process, according to an illustrative embodiment. The first frontside contact etching process includes forming openings 185 by removing portions of the vertical sidewalls 154, the dielectric fill layer 168, the ILD layer 170, the metal liner layer 183, and the conductive layer 182 to expose the silicide portions 184 positioned above the source/drain region 126. According to an embodiment, the openings 185 can be formed using, for example, a dry etching process (e.g., RIE or IBE), a wet chemical etching process, or a combination of these etching processes.

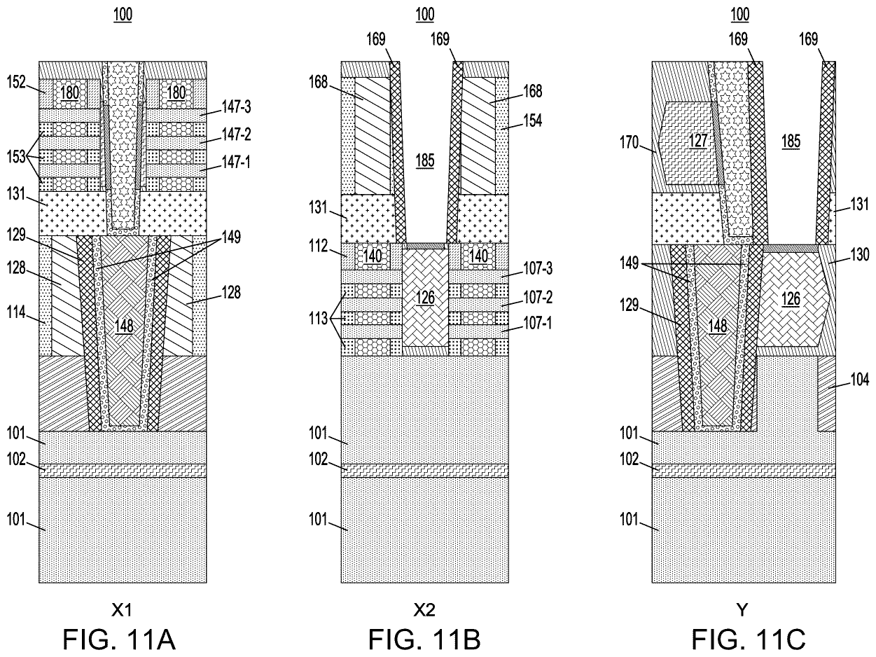

FIGS. 11A-11C show cross-sectional views, which respectively correspond to the lines X1, X2, and Y in FIG. 1 of the semiconductor structure 100 following deposition and recessing of a dielectric liner layer 169, according to an illustrative embodiment. The dielectric liner layer 169 is formed on the sides and bottom of the openings 185, and an etching process removes the bottom portion of the dielectric liner layer 169 to expose the silicide portions 184 positioned above the source/drain region 126. The dielectric liner layer 169 may be formed using similar techniques and materials as described for the dielectric liner layer 129, for example.

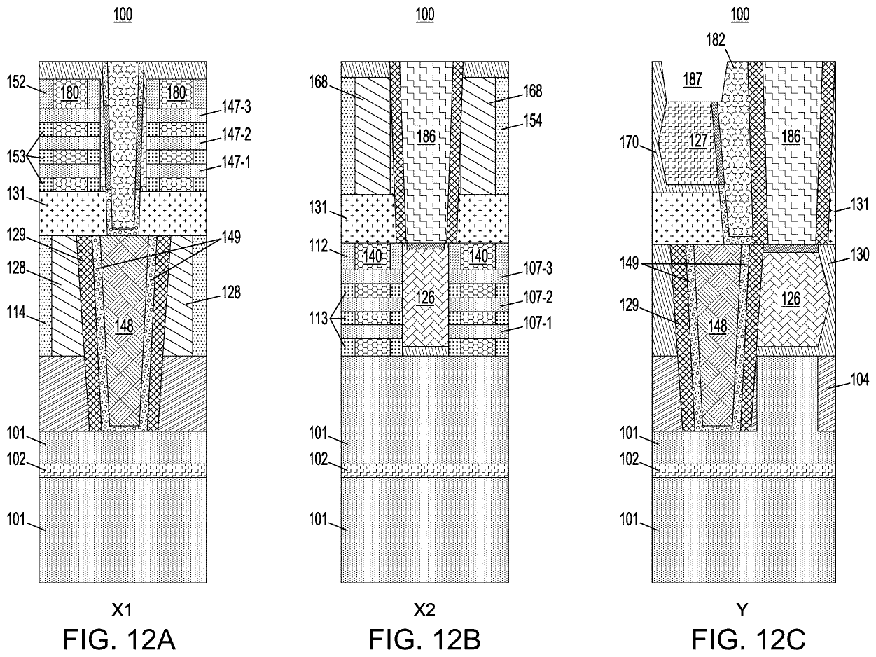

FIGS. 12A-12C show cross-sectional views, which respectively correspond to the lines X1, X2, and Y in FIG. 1 of the semiconductor structure 100 following a second frontside contact etching process using an organic planarization layer (OPL) 186, according to an illustrative embodiment. The OPL 186 can be deposited on the top surface of the semiconductor structure 100 to fill in the openings 185. The OPL 186 can be formed of an organic polymer such as carbon, hydrogen, and/or nitrogen, for example. The OPL 186 can then be patterned to expose areas above the source/drain region 127 that are to be recessed. One or more etching processes are subsequently performed to remove portions of the metal liner layer 183 and the conductive layer 182 to form opening 187.

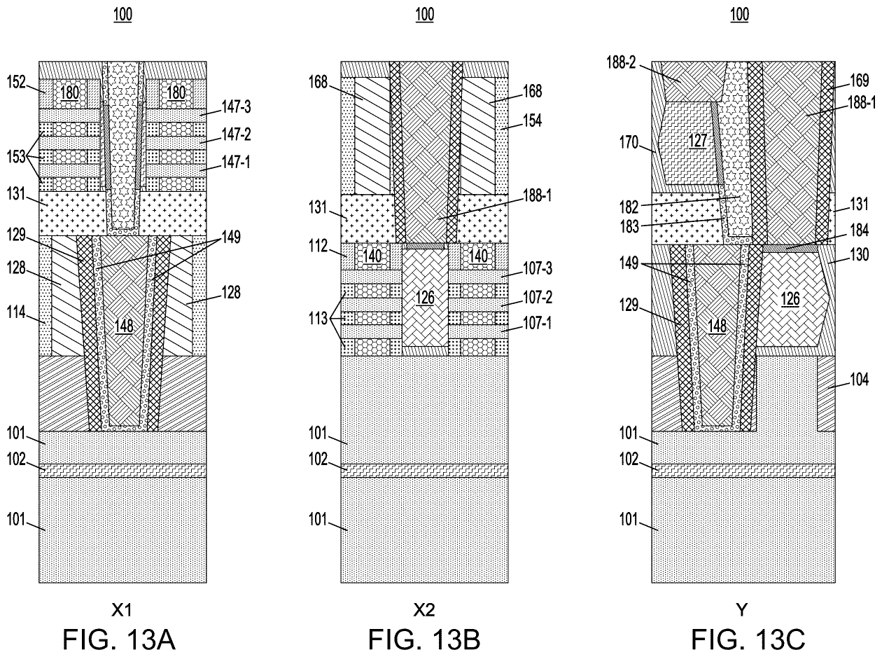

FIGS. 13A-13C show cross-sectional views, which respectively correspond to the lines X1, X2, and Y in FIG. 1 of the semiconductor structure 100 following an ashing process to remove the OPL 186 and formation of frontside source/drain contacts 188-1 and 188-2 (collectively “frontside source/drain contacts 188”), according to an illustrative embodiment. In some embodiments, the ashing process can strip the OPL 186 using oxygen plasma, nitrogen/hydrogen plasma, or other carbon stripping process. The frontside source/drain contact 188-1 is formed in the opening resulting from the ashing process and extends down contacting the silicide portion 184 corresponding to the source/drain region 126 as shown in FIGS. 12B and 12C. The frontside source/drain contact 188-2 is formed in the opening 187 and extends down to a top surface of the source/drain region 127 and the corresponding silicide portion 184 as shown in FIG. 12C.

The frontside source/drain contacts 188 can be formed of one or more metal layers comprising, for example, a silicide layer (such as Ni, Ti, NiPt, etc.), a metal adhesion layer (such as TiN), and a conductive metal fill layer (such as W, Al, Co, Ru, etc.) and can be deposited using, for example, deposition techniques such as CVD, PECVD, RFCVD, PVD, ALD, MBD, PLD, LSMCD, sputtering, and/or plating, followed by a planarization process, such as CMP, to remove excess portions of the metal layers from on top of the semiconductor structure 100.

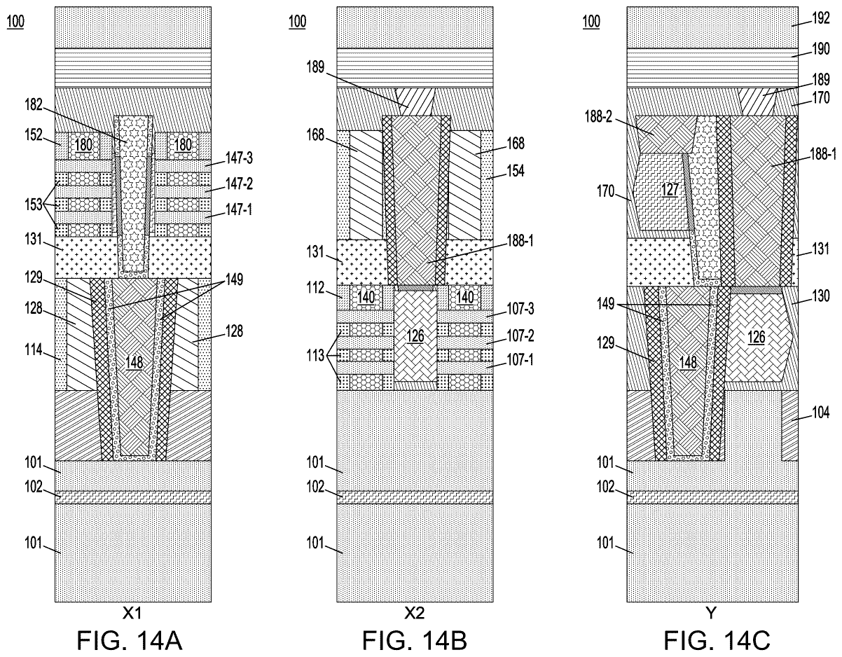

FIGS. 14A-14C show cross-sectional views, which respectively correspond to the lines X1, X2, and Y in FIG. 1 of the semiconductor structure 100 following frontside interconnect formation and carrier wafer bonding, according to an illustrative embodiment. Additional ILD material is deposited on the dielectric liner layer 169, conductive layer 182, and the frontside source/drain contacts 188 extending the ILD layer 170 upwards.

At least one frontside source/drain via 189 is formed in the ILD layer 170 to contact a top surface of the frontside source/drain contact 188-1. According to an embodiment, masks are formed on parts of the ILD layer 170 and exposed portions of the ILD layer 170 corresponding to where openings are to be formed are removed using a dry etching process (such as RIE or IBE), a wet chemical etching process, or a combination of these etching processes. The frontside source/drain via 189 can be formed in the opening to land on and contact the top surface of the frontside source/drain contact 188-1. The material of the frontside source/drain via 189 can comprise a conductive material such as W, Al, Cu, Co, Ru, Mo, or any other suitable conductive material.

Frontside back-end-of-line (BEOL) interconnects 190 are formed on the ILD layer 170 and include various BEOL interconnect structures. The frontside source/drain via 189 can connect the frontside source/drain contact 188-1 to the frontside BEOL interconnects 190, for example. A carrier wafer 192 may be formed of materials similar to those used in the semiconductor substrate 101 and can be formed over the frontside BEOL interconnects 190 using a wafer bonding process, such as dielectric-to-dielectric bonding.

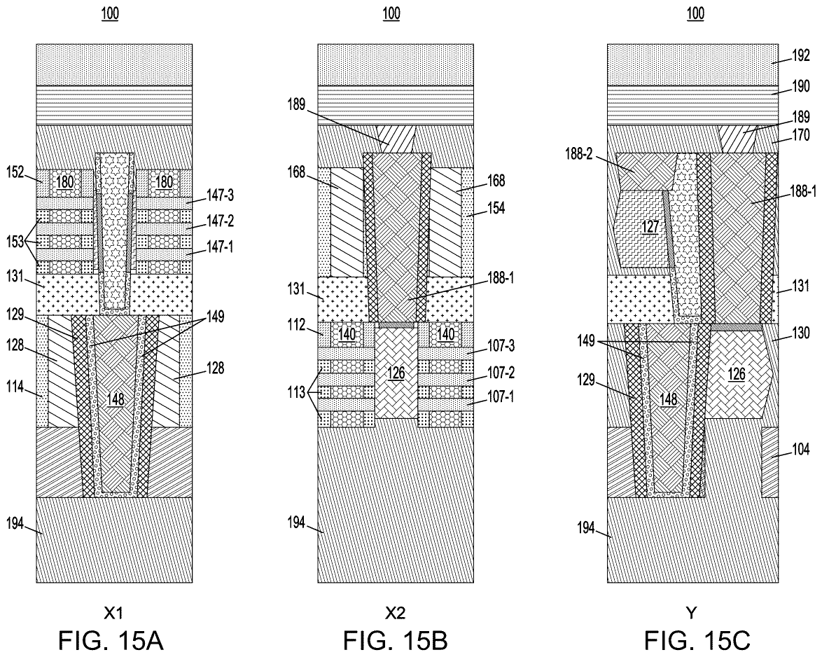

Referring now to FIGS. 15A-15C, using the carrier wafer 192, the semiconductor structure 100 may be “flipped” (for example, rotated 180 degrees) so that it is inverted. Additionally, the semiconductor substrate 101 is removed from the backside of the semiconductor structure 100 stopping at the etch stop layer 102. For example, the semiconductor substrate 101 can be selectively etched with an etchant that selectively etches silicon relative to a material of the etch stop layer 102. The etch stop layer 102 and the remaining semiconductor substrate 101 are also removed. The etching processes for removal of the etch stop layer 102 include, but are not limited to, IBE using Ar/CHF3 based chemistry. Etchants for removing the semiconductor substrate 101 include, for example, potassium hydroxide (KOH) and tetramethylammonium hydroxide (TMAH). A backside ILD layer 194 is deposited using deposition techniques such as CVD, PECVD, RFCVD, PVD, ALD, MBD, PLD, and/or LSMCD.

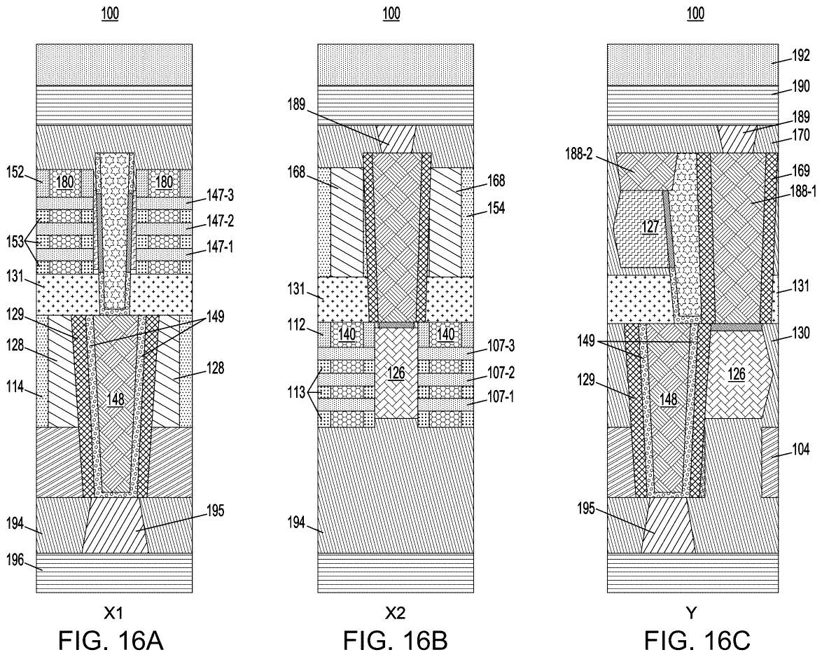

Referring now to FIGS. 16A-16C, the semiconductor structure 100 is shown following formation of at least one backside source/drain via 195 and BSPDN layers 196, according to an illustrative embodiment. The backside source/drain via 195 is formed in the backside ILD layer 194 to contact the bottom interlayer via comprising the metal liner layer 149 and the conductive layer 148. The backside source/drain via 195 can be formed using similar processes and materials as the frontside source/drain via 189.

The BSPDN layers 196 can comprise one or more layers formed on the backside ILD layer 194 and on the backside source/drain via 195. The BSPDN layers 196 can include various backside interconnect structures, such as power delivery network structures including, but not limited to, interconnects in a power supply path from voltage regulator modules (VRMs) to circuits. The interconnect structures can comprise, for example, power and ground planes in circuit boards, cables, connectors, and capacitors associated with a power supply. Backside power delivery prevents BEOL routing congestion, resulting in improved power performance benefits. In some embodiments, the BSPDN layers 196 can alternatively or additionally be used for signal routing, including power and/or clock signals as non-limiting examples.

Semiconductor devices and methods for forming the same in accordance with the above-described techniques can be employed in various applications, hardware, and/or electronic systems. Suitable hardware and systems for implementing embodiments of the invention may include, but are not limited to, personal computers, communication networks, electronic commerce systems, portable communications devices (e.g., cell and smart phones), solid-state media storage devices, functional circuitry, etc. Systems and hardware incorporating the semiconductor devices are contemplated embodiments of the invention. Given the teachings provided herein, one of ordinary skill in the art will be able to contemplate other implementations and applications of embodiments of the invention.

In some embodiments, the above-described techniques are used in connection with semiconductor devices that may require or otherwise utilize, for example, CMOSs, MOSFETs, and/or FinFETs. By way of non-limiting example, the semiconductor devices can include, but are not limited to CMOS, MOSFET, and FinFET devices, and/or semiconductor devices that use CMOS, MOSFET, and/or FinFET technology.

Various structures described above may be implemented in integrated circuits. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher-level carrier) or in a multichip package (such as a ceramic carrier that has either or both surface interconnections or buried interconnections). In any case the chip is then integrated with other chips, discrete circuit elements, and/or other signal processing devices as part of either: (a) an intermediate product, such as a motherboard, or (b) an end product. The end product can be any product that includes integrated circuit chips, ranging from toys and other low-end applications to advanced computer products having a display, a keyboard or other input device, and a central processor.

In an illustrative embodiment, a semiconductor device includes first and second source/drain regions, where the first source/drain region is at least partially laterally offset from the second source/drain region. The semiconductor device includes a first interlayer via extending into at least a portion of the first source/drain region, where the first interlayer via is isolated from the first source/drain region by a first dielectric liner, and a second interlayer via connected to the second source/drain region and to the first interlayer via, where the second interlayer via extends into at least a portion of the second source/drain region. The semiconductor device also includes a frontside contact connected to the first source/drain region, where the frontside contact is adjacent to, and isolated from, the second interlayer via.

In embodiments, the semiconductor device may further include a second dielectric liner that isolates the frontside contact from the second interlayer via.

In embodiments, the frontside contact may connect to at least one frontside interconnect structure.

In embodiments, the second interlayer via may include a metal fill layer and a metal liner layer covering at least one side of the metal fill layer that is connected to the first source/drain region.

In embodiments, at least a portion of an other side of the metal fill layer may not be covered by the metal liner layer.

In embodiments, the portion of the other side of the metal fill layer that is not covered by the metal liner layer may be adjacent to the frontside contact.

In embodiments, the first interlayer via may be connected to at least one backside interconnect structure.

In embodiments, a top surface of the first source/drain region may be below a level corresponding to a bottom surface of the second source/drain region.

In another embodiment, a semiconductor device includes a first transistor device comprising a first gate structure, a first source/drain region, a frontside source/drain contact connected to the first source/drain region, and a first set of channel layers connected to the first source/drain region. The semiconductor device includes a second transistor device vertically stacked with the first transistor device, comprising a second gate structure, a second source/drain region, and a second set of channel layers connected to the second source/drain region, where the first source/drain region does not vertically overlap with the second source/drain region. The semiconductor device also includes a first interlayer via extending into at least a portion of the first source/drain region, where the first interlayer via is isolated from the first source/drain region by a first dielectric liner, and a second interlayer via connected to the second source/drain region and to the first interlayer via. The frontside source/drain contact is adjacent to the second interlayer via and isolated from the second interlayer via by a second dielectric liner.

In embodiments, the frontside source/drain contact may connect to at least one frontside interconnect structure.

In embodiments, the first interlayer via may be connected to at least one backside interconnect structure.

In embodiments, the second interlayer via may include a metal fill layer and a metal liner layer covering at least one side of the metal fill layer that is connected to the first source/drain region.

In embodiments, the second interlayer via may include a metal fill layer and a metal liner layer. The metal liner layer may cover at least one side of the metal fill layer that is connected to the first source/drain region. At least a portion of an other side of the metal fill layer may be adjacent to the frontside source/drain contact and is not covered by the metal liner layer.

In embodiments, the second transistor device may be stacked above the first transistor device.

In embodiments, the first transistor device may include one of an n-type transistor device and a p-type transistor device, and the second transistor device may include the other one of the n-type transistor device and the p-type transistor device.

In embodiments, the first source/drain region and the second source/drain region may be positioned between the first gate structure and the second gate structure.

In yet another embodiment, a method includes forming a first source/drain region, forming a second source/drain region that is at least partially laterally offset from the first source/drain region forming a first interlayer via extending into at least a portion of the first source/drain region, where the first interlayer via is isolated from the first source/drain region by a first dielectric liner. The method includes forming a second interlayer via connected to the second source/drain region and to the first interlayer via, where the second interlayer via extends into at least a portion of the second source/drain region, and forming a frontside contact connected to the first source/drain region, where the frontside contact is adjacent to, and isolated from, the second interlayer via.

In embodiments, the method may further include forming a second dielectric liner that isolates the frontside contact from the second interlayer via.

In embodiments, forming the second interlayer via may include: forming a metal fill layer; forming a metal liner layer, wherein the metal liner layer surrounds the metal fill layer; and removing at least a portion of the metal fill metal liner corresponding to a side of the second interlayer via that is adjacent to the frontside contact.

In embodiments, the method may further include connecting the frontside contact to at least one frontside interconnect structure and connecting the first interlayer via to at least one backside interconnect structure.

Conventional techniques for designing and fabricating stacked semiconductor devices with staggered active regions often need to compromise between reliability and cell height. Without in any way limiting the scope, interpretation, or application of the claims appearing below, a technical effect of one or more of the example embodiments disclosed herein is enhancing the performance and reliability of stacked semiconductor devices with staggered active regions without increasing cell height. For example, at least some embodiments provide reliable fabrication techniques that incorporate dielectric barrier layers and/or interlayer via structures (e.g., dielectric liner layers 129 and 169 in the semiconductor structure 100 shown in FIGS. 16A-16C) to mitigate the likelihood of shorts between source/drain regions and other components within a stacked semiconductor structure with staggered active regions. Furthermore, at least some embodiments can help avoid misalignment issues involving one or more source/drain regions that often occur with conventional techniques. For example, by employing dielectric liners around interlayer vias, shorts to adjacent regions (e.g., a bottom source/drain region) are prevented, while still allowing a broad contact area to the top source/drain region, thereby reducing contact resistance and enhancing performance.

It should be understood that the various layers, structures, and regions shown in the figures are schematic illustrations that are not drawn to scale. In addition, for ease of explanation, one or more layers, structures, and regions of a type commonly used to form semiconductor devices or structures may not be explicitly shown in a given figure. This does not imply that any layers, structures, and regions not explicitly shown are omitted from the actual semiconductor structures. Furthermore, it is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description.

Moreover, the same or similar reference numbers are used throughout the figures to denote the same or similar features, elements, or structures, and thus, a detailed explanation of the same or similar features, elements, or structures are not repeated for each of the figures. It is to be understood that the terms “approximately” or “substantially” as used herein with regard to thicknesses, widths, percentages, ranges, temperatures, times, and other process parameters, etc., are meant to denote being close or approximate to, but not exactly. For example, the term “approximately” or “substantially” as used herein implies that a small margin of error is present, such as ±5%, preferably less than 2% or 1% or less than the stated amount.

In the description above, various materials, dimensions and processing parameters for different elements are provided. Unless otherwise noted, such materials are given by way of example only and embodiments are not limited solely to the specific examples given. Similarly, unless otherwise noted, all dimensions and process parameters are given by way of example and embodiments are not limited solely to the specific dimensions or ranges given.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor device comprising:
first and second source/drain regions, wherein the first source/drain region is at least partially laterally offset from the second source/drain region;
a first interlayer via extending into at least a portion of the first source/drain region, wherein the first interlayer via is isolated from the first source/drain region by a first dielectric liner;
a second interlayer via connected to the second source/drain region and to the first interlayer via, wherein the second interlayer via extends into at least a portion of the second source/drain region; and
a frontside contact connected to the first source/drain region, wherein the frontside contact is adjacent to, and isolated from, the second interlayer via.

2. The semiconductor device of claim 1, further comprising:
a second dielectric liner that isolates the frontside contact from the second interlayer via.

3. The semiconductor device of claim 1, wherein the frontside contact connects to at least one frontside interconnect structure.

4. The semiconductor device of claim 1, wherein the second interlayer via comprises a metal fill layer and a metal liner layer covering at least one side of the metal fill layer that is connected to the first source/drain region.

5. The semiconductor device of claim 4, wherein at least a portion of an other side of the metal fill layer is not covered by the metal liner layer.

6. The semiconductor device of claim 5, wherein the portion of the other side of the metal fill layer that is not covered by the metal liner layer is adjacent to the frontside contact.

7. The semiconductor device of claim 1, wherein the first interlayer via is connected to at least one backside interconnect structure.

8. The semiconductor device of claim 1, wherein a top surface of the first source/drain region is below a level corresponding to a bottom surface of the second source/drain region.

9. A semiconductor device comprising:
a first transistor device comprising a first gate structure, a first source/drain region, a frontside source/drain contact connected to the first source/drain region, and a first set of channel layers connected to the first source/drain region;
a second transistor device vertically stacked with the first transistor device, comprising a second gate structure, a second source/drain region, and a second set of channel layers connected to the second source/drain region, wherein the first source/drain region does not vertically overlap with the second source/drain region;
a first interlayer via extending into at least a portion of the first source/drain region, wherein the first interlayer via is isolated from the first source/drain region by a first dielectric liner; and
a second interlayer via connected to the second source/drain region and to the first interlayer via;
wherein the frontside source/drain contact is adjacent to the second interlayer via and isolated from the second interlayer via by a second dielectric liner.

10. The semiconductor device of claim 9, wherein the frontside source/drain contact connects to at least one frontside interconnect structure.

11. The semiconductor device of claim 9, wherein the first interlayer via is connected to at least one backside interconnect structure.

12. The semiconductor device of claim 9, wherein the second interlayer via comprises a metal fill layer and a metal liner layer covering at least one side of the metal fill layer that is connected to the first source/drain region.

13. The semiconductor device of claim 9, wherein the second interlayer via comprises a metal fill layer and a metal liner layer, wherein:
the metal liner layer covers at least one side of the metal fill layer that is connected to the first source/drain region; and
at least a portion of an other side of the metal fill layer is adjacent to the frontside source/drain contact and is not covered by the metal liner layer.

14. The semiconductor device of claim 9, wherein the second transistor device is stacked above the first transistor device.

15. The semiconductor device of claim 9, wherein the first transistor device comprises one of an n-type transistor device and a p-type transistor device, and the second transistor device comprises an other one of the n-type transistor device and the p-type transistor device.

16. The semiconductor device of claim 9, wherein the first source/drain region and the second source/drain region are positioned between the first gate structure and the second gate structure.

17. A method comprising:
forming a first source/drain region;
forming a second source/drain region that is at least partially laterally offset from the first source/drain region;
forming a first interlayer via extending into at least a portion of the first source/drain region, wherein the first interlayer via is isolated from the first source/drain region by a first dielectric liner;
forming a second interlayer via connected to the second source/drain region and to the first interlayer via, wherein the second interlayer via extends into at least a portion of the second source/drain region; and
forming a frontside contact connected to the first source/drain region, wherein the frontside contact is adjacent to, and isolated from, the second interlayer via.

18. The method of claim 17, further comprising:
forming a second dielectric liner that isolates the frontside contact from the second interlayer via.

19. The method of claim 17, wherein forming the second interlayer via includes:
forming a metal fill layer;
forming a metal liner layer, wherein the metal liner layer surrounds the metal fill layer; and
removing at least a portion of the metal fill metal liner corresponding to a side of the second interlayer via that is adjacent to the frontside contact.

20. The method of claim 17, further comprising:
connecting the frontside contact to at least one frontside interconnect structure; and
connecting the first interlayer via to at least one backside interconnect structure.
